(19) United States
(12) Patent Application Publication
(10) Pub. No.: US 2026/0149409 A1
(43) Pub. Date: May 28, 2026

(54) RECONFIGURABLE MULTI-CORE VOLTAGE-CONTROLLED OSCILLATOR CIRCUIT

(71) Applicant: Samsung Electronics Co., Ltd., Gyeonggi-do (KR)

(72) Inventors: Zhiyu CHEN, San Jose, CA (US); Wanghua WU, Santa Clara, CA (US)

(21) Appl. No.: 19/369,887

(22) Filed: Oct. 27, 2025

Related U.S. Application Data
(60) Provisional application No. 63/723,796, filed on Nov. 22, 2024.

(51) Int. Cl. H03B 5/12

(52) U.S. Cl. CPC H03B 5/1212

(57) ABSTRACT

A voltage-controlled oscillator (VCO) circuit is provided. The VCO includes: a first dual-core VCO including a first oscillator core and a second oscillator core; a second dual-core VCO including a third oscillator core and a fourth oscillator core, wherein the first and second dual-core VCOs are disposed side-by-side; first switches configured to connect or disconnect the first and second dual-core VCOs from each other; and second switches configured to connect or disconnect the first and second oscillator from each other, and to connect or disconnect the third and fourth oscillator cores from each other.

### CROSS-REFERENCE TO RELATED APPLICATION

This application claims the priority benefit under 35 U.S.C. § 119(e) of U.S. Provisional Application No. 63/723,796, filed on Nov. 22, 2024, the disclosure of which is incorporated by reference in its entirety as if fully set forth herein.

### TECHNICAL FIELD

The disclosure generally relates to voltage-controlled oscillators (VCOs). More particularly, the subject matter disclosed herein relates to improvements to multi-core VCOs with reconfigurable operating modes.

### SUMMARY

VCOs are widely used in radio-frequency and millimeter-wave communication systems. To achieve low phase noise and wide tuning ranges, multi-core and coupled VCOs have been developed.

Some VCOs have employed coupled inductors, cross-coupled transistors, and switching networks to provide some degree of mode reconfiguration between cores, such as dual-core or quad-core operation.

However, multi-core VCOs often suffer from unwanted oscillation modes, increased layout area, and limited flexibility when switching between modes. These limitations prevent efficient scaling of phase noise performance with power consumption.

To overcome these issues, systems and methods are described herein for providing an area-efficient, reconfigurable VCO. In particular, the VCO includes first switches that selectively couple or decouple dual-core VCOs disposed side-by-side, and second switches that selectively couple or decouple oscillator cores within each dual-core VCO. This dual-class switching scheme enables quad-core, dual-core, and single-core modes of operation while suppressing unwanted oscillation modes and decoupling inactive cores.

The above approaches improve on previous methods because they reduce layout area, minimize parasitic loading, and provide reliable suppression of spurious modes. As a result, the disclosed VCO achieves improved phase noise scalability with power consumption, making it well-suited for millimeter-wave communication systems.

In an embodiment, a VCO circuit comprises a first dual-core VCO including a first oscillator core and a second oscillator core; a second dual-core VCO including a third oscillator core and a fourth oscillator core, wherein the first and second dual-core VCOs are disposed side-by-side; first switches configured to connect or disconnect the first and second dual-core VCOs from each other; and second switches configured to connect or disconnect the first and second oscillator from each other, and to connect or disconnect the third and fourth oscillator cores from each other.

In an embodiment, a transceiver comprises a VCO including: a first dual-core VCO including a first oscillator core and a second oscillator core; a second dual-core VCO including a third oscillator core and a fourth oscillator core, wherein the first and second dual-core VCOs are disposed side-by-side; first switches configured to connect or disconnect the first and second dual-core VCOs from each other; and second switches configured to connect or disconnect the first and second oscillator from each other, and to connect or disconnect the third and fourth oscillator cores from each other.

In an embodiment, a method of operating a VCO circuit comprises selectively turning on or off first switches to connect or disconnect a first dual-core VCO and a second dual-core VCO from each other, wherein the first and second dual-core VCOs are disposed side-by-side; and selectively turning on or off second switches to connect or disconnect first and second oscillator cores of the first dual-core VCO from each other, and to connect or disconnect the third and fourth oscillator cores of the second dual-core VCO from each other.

### BRIEF DESCRIPTION OF THE DRAWINGS

In the following section, the aspects of the subject matter disclosed herein will be described with reference to exemplary embodiments illustrated in the figures, in which:

FIG. 1 is a diagram of a reconfigurable VCO circuit including first and second dual-core VCOs disposed side-by-side and switching circuitry for enabling quad-core, dual-core, and single-core operation, according to an embodiment;

FIG. 2 is a simplified diagram of switching circuitry for selectively coupling dual-core VCOs and oscillator cores to enable reconfigurable operation, according to an embodiment;

FIG. 3 is a simplified diagram illustrating current flow in a reconfigurable multi-core VCO circuit illustrating operation in a quad-core mode, according to an embodiment;

FIG. 4 is a diagram of a reconfigurable VCO circuit illustrating operation in a dual-core mode, according to an embodiment;

FIG. 5A is a diagram of a dual-core VCO operating in a desired mode in which no current flows through the switching transistors, according to an embodiment;

FIGS. 5B and 5C are diagrams of a VCO operating in undesired modes in which current flows through the switching transistors, according to an embodiment;

FIG. 6 is a schematic diagram illustrating operation of the VCO in a single-core mode, according to an embodiment;

FIG. 7 is a flowchart illustrating a method of operating a VCO circuit, according to an embodiment;

FIG. 8 is a block diagram of an electronic device in a network environment, according to an embodiment; and

FIG. 9 shows a system including a UE and a gNB in communication with each other.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms and a plural term may include the corresponding singular form. Similarly, a hyphenated term (e.g., “two-dimensional,” “pre-determined,” “pixel-specific,” etc.) may be occasionally interchangeably used with a corresponding non-hyphenated version (e.g., “two dimensional,” “predetermined,” “pixel specific,” etc.), and a capitalized entry (e.g., “Counter Clock,” “Row Select,” “PIXOUT,” etc.) may be interchangeably used with a corresponding non-capitalized version (e.g., “counter clock,” “row select,” “pixout,” etc.). Such occasional interchangeable uses shall not be considered inconsistent with each other.

Also, depending on the context of discussion herein, a singular term may include the corresponding plural forms and a plural term may include the corresponding singular form. It is further noted that various figures (including component diagrams) shown and discussed herein are for illustrative purpose only, and are not drawn to scale. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement some of the example embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, the term “module” refers to any combination of software, firmware and/or hardware configured to provide the functionality described herein in connection with a module. For example, software may be embodied as a software package, code and/or instruction set or instructions, and the term “hardware,” as used in any implementation described herein, may include, for example, singly or in any combination, an assembly, hardwired circuitry, programmable circuitry, state machine circuitry, and/or firmware that stores instructions executed by programmable circuitry. The modules may, collectively or individually, be embodied as circuitry that forms part of a larger system, for example, but not limited to, an integrated circuit (IC), system on-a-chip (SoC), an assembly, and so forth.

“VCO” as used herein may refer to voltage-controlled oscillator configured to generate an oscillating signal whose frequency is controlled by an input voltage. Some examples of “VCO” may include LC-based oscillators, ring oscillators, or multi-core coupled oscillators used in frequency synthesizers and transceivers. “Dual-core VCO” as used herein may refer to a VCO formed of two oscillator cores that are selectively coupled to operate together or independently. Some examples of “dual-core VCO” may include two LC oscillator cores sharing a coupling network, two oscillator cores coupled through transistor switches, or oscillator cores arranged side-by-side with inductors and capacitors configured for magnetic or resistive coupling. “Oscillator core” as used herein may refer to an oscillator that generates a periodic signal, which may include an active device arrangement (e.g., cross-coupled transistors) and a resonant element (e.g., an inductor and capacitor circuit). Some examples of “oscillator core” may include LC oscillator cores, ring oscillator cores, or cross-coupled transistor oscillator cores employed in VCOs.

“First switches” as used herein may refer to switching elements that selectively connect or disconnect two dual-core VCOs from each other, such that oscillator cores of one dual-core VCO may be coupled to corresponding oscillator cores of another dual-core VCO. Some examples of “first switches” may include MOSFET transistors, transmission gates, or other semiconductor switching devices used to couple inductors of different dual-core VCOs. “Second switches” as used herein may refer to switching elements that selectively connect or disconnect oscillator cores within a given dual-core VCO, such that the two oscillator cores of the dual-core VCO may be coupled together or operated independently. Some examples of “second switches” may include MOSFET transistors, transmission gates, or other semiconductor switching devices used to couple inductors of oscillator cores within the same dual-core VCO.

“Inductors” as used herein may refer to passive circuit elements that store energy in a magnetic field when current flows through them, and that form part of the resonant circuit of an oscillator core. Some examples of “inductors” may include spiral inductors, differential inductors, figure-8 inductors, or parallel-coupled inductors. “Quad-core mode” as used herein may refer to an operating state of the VCO circuit in which all four oscillator cores are coupled together to operate simultaneously. Some examples of “quad-core mode” may include configurations where both the first and second switches are turned on to connect inductors of the two dual-core VCOs to allow all four cores to oscillate in a coupled manner. “Dual-core mode” as used herein may refer to an operating state of the VCO circuit in which only two oscillator cores within a selected dual-core VCO are coupled to operate together, while the other dual-core VCO is disabled or decoupled. Some examples of “dual-core mode” may include configurations where the first switches are turned off to disconnect the two dual-core VCOs, and the second switches within one dual-core VCO are turned on to couple its two oscillator cores. “Single-core mode” as used herein may refer to an operating state of the VCO circuit in which only one oscillator core is active, and the other oscillator cores are disabled or decoupled from the active core. Some examples of “single-core mode” may include configurations where both the first switches and the second switches are turned off, such that a single oscillator core oscillates independently. “Reconfigure” as used herein may refer to the ability of changing operational configurations between quad-, dual-, and single-core mode of the VCO. “Couple” as used herein may refer to the transfer of energy or signals between two or more circuits or components. Some examples of “coupling” may include the interaction or connection between two or more oscillators that exchange energy through capacitive or inductive effects, leading to synchronization of their phase and frequency.

The present disclosure describes a VCO circuit that integrates multiple dual-core oscillators with configurable switching structures. In particular, the present disclosure provides a first dual-core VCO and a second dual-core VCO arranged side-by-side, with first switches selectively coupling the two dual-core VCOs and second switches selectively coupling oscillator cores within each dual-core VCO. This arrangement provides multiple operation modes, including quad-core, dual-core, and single-core modes. By dynamically turning the switches on or off, the VCO circuit allows precise control over which cores are active and how they interact, providing tunability, reconfigurability, and reduced mode interference.

The VCO circuit may also incorporate inductor structures, such as figure-8 layouts, to enhance magnetic coupling between cores while maintaining compact integration. In some embodiments, the horizontal distance between the first and second dual-core VCOs may be in the range of about 10 to 50 micrometers. Further, the first switches may include transistors sized in the range of about 10 to 50 micrometers, while the second switches may include transistors sized in the range of about 50 to 200 micrometers. Together, these features can provide a scalable, multi-core VCO capable of supporting high-frequency applications such as millimeter-wave communication systems, while offering improved suppression of unwanted oscillation modes, efficient core decoupling, and enhanced frequency stability.

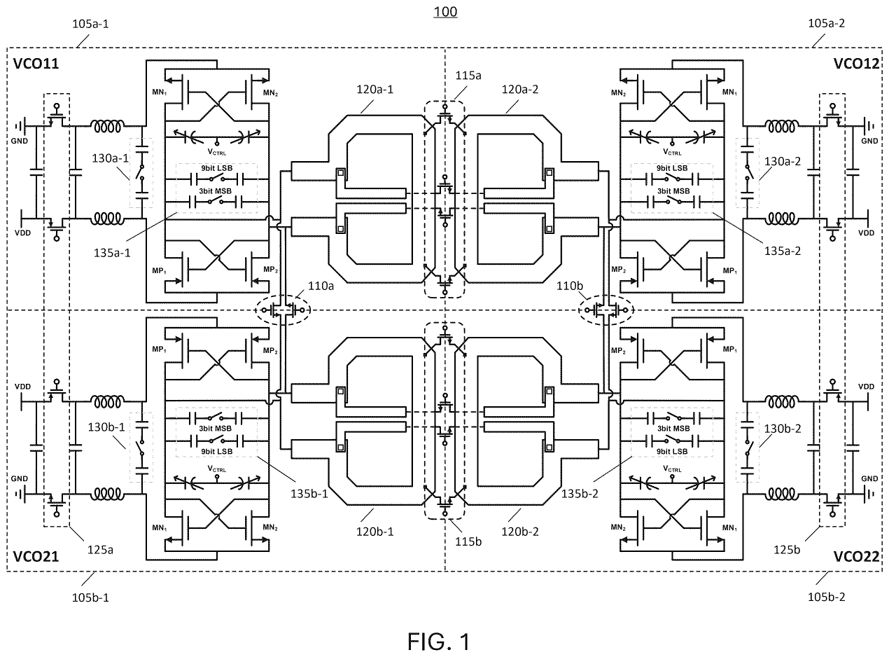

FIG. 1 is a diagram of a reconfigurable VCO circuit including first and second dual-core VCOs disposed side-by-side and switching circuitry for enabling quad-core, dual-core, and single-core operation, according to an embodiment.

The VCO circuit 100 may include a first dual-core VCO 105a formed of oscillator cores 105a-1 (VCO11) and 105a-2 (VCO12), and a second dual-core VCO 105b formed of oscillator cores 105b-1 (VCO21) and 105b-2 (VCO22). The first and second dual-core VCOs 105a and 105b may be disposed side-by-side in a horizontal orientation, which may reduce routing complexity, improve symmetry in coupling paths, and minimize mismatch between cores. The first and second dual-core VCOs 105a and 105b may be placed in close physical proximity to one another, separated by a horizontal spacing in the range of about 10 micrometers to 50 micrometers, such that parasitic imbalances can be minimized and coupling through first switches 110a and 110b can be implemented with reduced interconnect resistance. This compact arrangement may also facilitate efficient layout utilization and enhance phase coherence across the oscillator cores.

The VCO circuit 100 may further include first switches 110a and 110b that couple inductors 120a-1 and 120b-1, and 120a-2 and 120b-2, of the respective oscillator cores 105a-1, 105b-1 and 105a-2, 105b-2. In operation, the first switches 110a and 110b may be configured to connect or disconnect the first dual-core VCO 105a and the second dual-core VCO 105b from each other. In one embodiment, the first switches 110a and 110b may be implemented as transistors having a channel size in the range of about 10 micrometers to 50 micrometers. This sizing can enable reliable coupling of inductors with low on-resistance while limiting parasitic capacitance that could otherwise degrade oscillation frequency or phase noise.

The second switches 115a and 115b may be provided between oscillator cores within each dual-core VCO, for example, between oscillator cores 105a-1 and 105a-2, and between oscillator cores 105b-1 and 105b-2, respectively. The second switches 115a and 115b may allow the oscillator cores within each dual-core VCO to be selectively connected or disconnected. In one embodiment, the second switches 115a and 115b may be implemented as transistors having a large channel size in the range of about 50 micrometers to 200 micrometers. The large transistor sizing may allow the second switches 115a and 115b to suppress unwanted oscillation modes in dual-core operation and ensure decoupling of inactive oscillator cores in single-core operation, while maintaining robust current handling capacity.

By employing small transistors for the first switches 110a and 110b and larger transistors for the second switches 115a and 115b, the VCO circuit 100 can achieve improved mode selectivity and performance. The smaller first switches 110a and 110b can minimize parasitic capacitance, enabling efficient coupling and decoupling of the dual-core VCOs 105a and 105b when switching between quad-core and independent operation. Conversely, the larger second switches 115a and 115b can provide strong isolation and current handling within each dual-core VCO, thereby suppressing undesired oscillation modes in dual-core operation and ensuring reliable decoupling of inactive cores in single-core operation.

Each oscillator core may include an inductor. For example, oscillator core 105a-1 may include inductor 120a-1, oscillator core 105a-2 may include inductor 120a-2, oscillator core 105b-1 may include inductor 120b-1, and oscillator core 105b-2 may include inductor 120b-2. Inductor 120a-1 may be coupled to inductor 120b-1 via switch 110a, and inductor 120a-2 may be coupled to inductor 120b-2 via switch 110b. In this way, the inductors of corresponding oscillator cores can be magnetically and electrically coupled or isolated depending on the switching state. In one embodiment, the inductors 120a-1 and 120a-2, and 120b-1 and 120b-2 may be implemented as octagonal metal lines having diameters in the range of about 100 micrometers to 250 micrometers, and typical inductance in the range of about 100 picohenry to 200 picohenry.

Power-related switches 125a and 125b are disposed between supply rails (VDD/GND) and inductors of the respective oscillator cores. In some embodiments, these switches may receive mode control signals to enable or disable specific oscillator cores depending on the operating mode of the VCO circuit 100 (e.g., quad-core mode, dual-core mode, or single-core mode).

Each oscillator core may further include tuning and biasing components. In particular, oscillator core 105a-1 may include a 3-bit tail capacitor 130a-1 and tuning capacitors 135a-1, which may comprise 9-bit and 3-bit capacitor banks. Oscillator core 105a-2 may include a 3-bit tail capacitor 130a-2 and tuning capacitors 135a-2. Similarly, oscillator core 105b-1 may include a 3-bit tail capacitor 130b-1 and tuning capacitors 135b-1, while oscillator core 105b-2 may include a 3-bit tail capacitor 130b-2 and tuning capacitors 135b-2. These capacitive elements can provide fine-grain control over oscillation frequency and phase alignment among the cores. In one embodiment, the oscillation frequency of the VCO may be in the range of about 10 gigahertz to 30 gigahertz with frequency tuning range of about 5% to 40% of oscillation center frequency.

Each of the oscillator cores 105a-1, 105a-2, 105b-1, and 105b-2 may include a transistor arrangement of NMOS and PMOS devices. In one embodiment, each oscillator core may include transistors MN1, MN2, MP1 and MP2, which are arranged in a cross-coupled configuration. The size of transistors of each core may be in the range of 5 micrometers to 30 micrometers.

The arrangement of the dual-core VCOs 105a and 105b, the first switches 110a and 110b, the second switches 115a and 115b, and the selectively coupled inductors 120a-1, 120a-2, 120b-1, and 120b-2, can enable the VCO circuit 100 to flexibly operate in multiple modes. These can include a quad-core mode, in which all oscillator cores are coupled; a dual-core mode, in which one or more oscillator core pairs are coupled while others are isolated; and a single-core mode, in which only one oscillator core operates while others are decoupled. The side-by-side configuration of the dual-core VCOs can enhance layout symmetry and minimize coupling asymmetry, while the tailored transistor sizes for the first and second switches can improve mode selectivity, reduce phase noise, and support energy-efficient operation across the different modes.

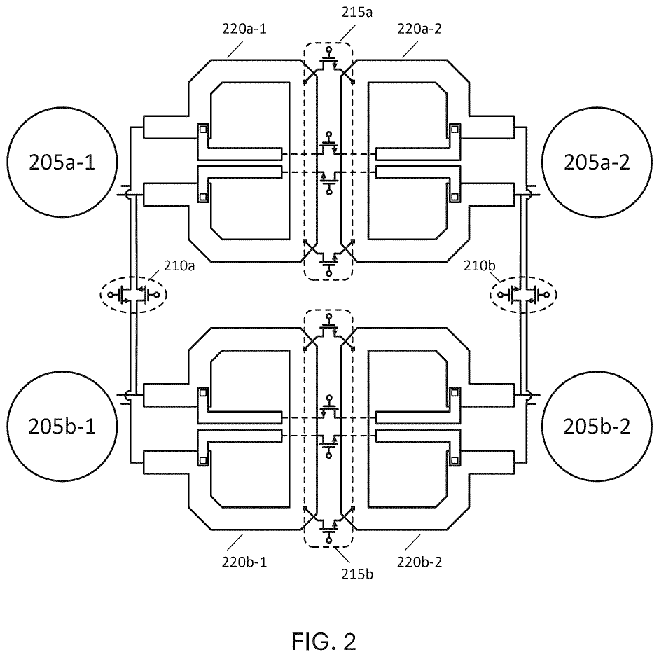

FIG. 2 is a simplified diagram of switching circuitry for selectively coupling dual-core VCOs and oscillator cores to enable reconfigurable operation, according to an embodiment. Each of the elements shown in FIG. 2 may correspond to a detailed circuit-level implementation illustrated in FIG. 1. For example, first switches 210a may correspond to the first switches 110a and second switches 215a may correspond to the second switches 115a.

As shown in FIG. 2, the VCO circuit may include dual-core VCOs 205a-1, 205a-2 and 205b-1, 205b-2 arranged side-by-side. Inductors 220a-1 and 220a-2 may correspond to the oscillator cores of the first dual-core VCO 205a, while inductors 220b-1 and 220b-2 may correspond to the oscillator cores of the second dual-core VCO 205b. First switches 210a and 210b may be provided between the dual-core VCOs to selectively couple or decouple inductors 220a-1 and 220b-1, and inductors 220a-2 and 220b-2, respectively. Second switches 215a and 215b may be provided within each dual-core VCO to selectively couple or decouple the oscillator cores and their respective inductors 220a-1, 220a-2 and 220b-1, 220b-2.

In the arrangement of FIG. 2, to reduce the occupied area of the multi-core VCO and to enable scalable core operation for balancing phase noise and power consumption, two closely placed dual-core VCOs 205a and 205b are employed, with added coupling transistors (shown as first switches 210a, 210b). In this way, multi-core operation is achieved through both resistive coupling and substrate coupling, which may allow the coupling transistor size to be minimized so that the parasitic capacitance may be reduced. Furthermore, the modified parallel-coupled figure-8 inductors 220a-1, 220a-2, 220b-1, and 220b-2 use transistor switches to provide resistance for unwanted-mode suppression when activated, while decoupling the inactive cores when operating in single-core mode.

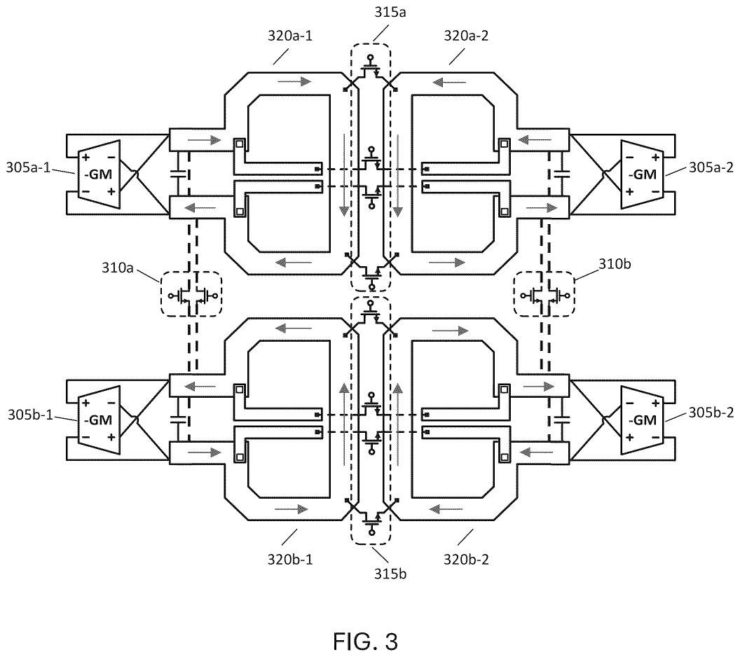

FIG. 3 is a simplified diagram illustrating current flow in a reconfigurable multi-core VCO circuit illustrating operation in a quad-core mode, according to an embodiment. Each of the elements shown in FIG. 3 may correspond to the detailed circuit-level implementation of FIG. 1 and the simplified switching configuration of FIG. 2. In this embodiment, the first dual-core VCO 305a and the second dual-core VCO 305b are illustrated in the form of resistance generators, denoted as-GM blocks, which represent the negative resistance provided by the cross-coupled transistor pairs sustaining oscillation in each oscillator core.

FIG. 3 further depicts inductors 320a-1, 320a-2, 320b-1, and 320b-2 arranged in a figure-8 configuration, interconnected through first switches 310a and 310b and second switches 315a and 315b. In the quad-core mode shown, all switches are activated such that each oscillator core of the dual-core VCOs 305a and 305b is magnetically and electrically coupled. The directional arrows shown within the inductors 320a-1, 320a-2, 320b-1, and 320b-2 represent the flow of current in the coupled oscillation paths. Specifically, the arrows indicate alternating bidirectional current flow that circulates in complementary directions between the inductors 320a-1, 320a-2, 320b-1, and 320b-2, thereby reinforcing the coupling of the oscillators and stabilizing the quad-core operation.

By representing the dual-core VCOs 305a and 305b as negative resistance generators (−GM), FIG. 3 emphasizes the functional role of the active transistor devices in compensating resonator losses and sustaining oscillation. The integration of resistive coupling through the first switches 310a, 310b and intra-dual-core coupling through the second switches 315a, 315b may enable the four oscillator cores to operate in quad-core mode. This arrangement enhances phase coherence and reduces phase noise by distributing the effective negative resistance across all four cores while maintaining balanced current flow, as shown by the directional arrows.

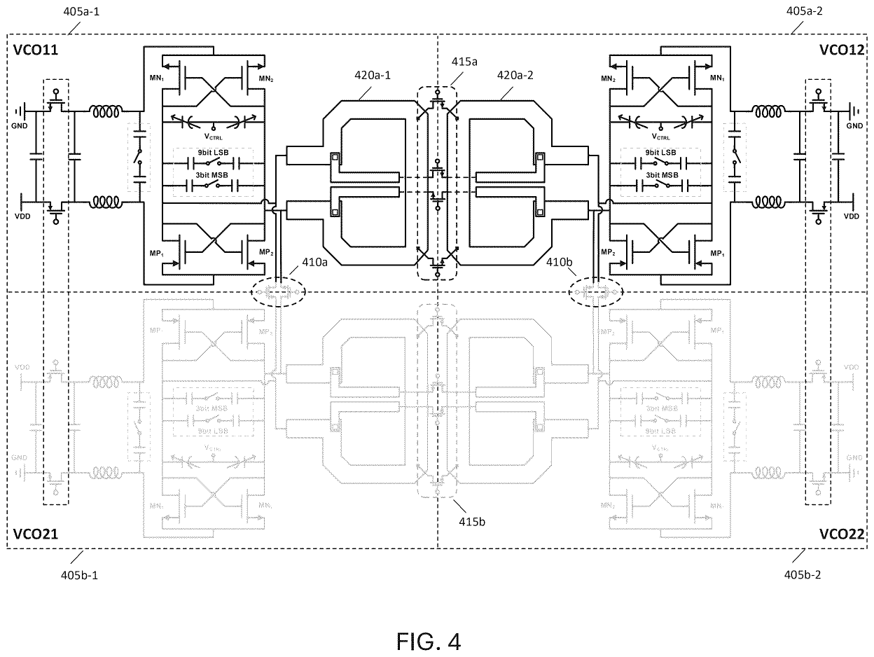

FIG. 4 is a diagram of a reconfigurable VCO circuit illustrating operation in a dual-core mode, according to an embodiment. The elements shown in FIG. 4 correspond to those of FIG. 1, but are denoted with reference numerals in the 400 series. In this mode, only the upper oscillator cores 405a-1 (VCO11) and 405a-2 (VCO12) are active, while the lower oscillator cores 405b-1 (VCO21) and 405b-2 (VCO22) are turned off. The first switches 410a and 410b that would otherwise couple the lower oscillator cores are also turned off, thereby isolating the inactive cores from the circuit.

The second switches 415a and 415b, configured as 2-to-1 core switches, may be activated to couple the inductors of the active oscillator cores 405a-1 and 405a-2. This selective coupling may enable dual-core operation with resistive and substrate coupling paths between the two active cores, while suppressing unwanted oscillation modes. By maintaining coupling between only the upper oscillator cores and disabling both the lower oscillator cores and the 2-to-4-core switches, the circuit achieves stable dual-core operation with reduced power consumption and improved phase noise characteristics relative to quad-core operation.

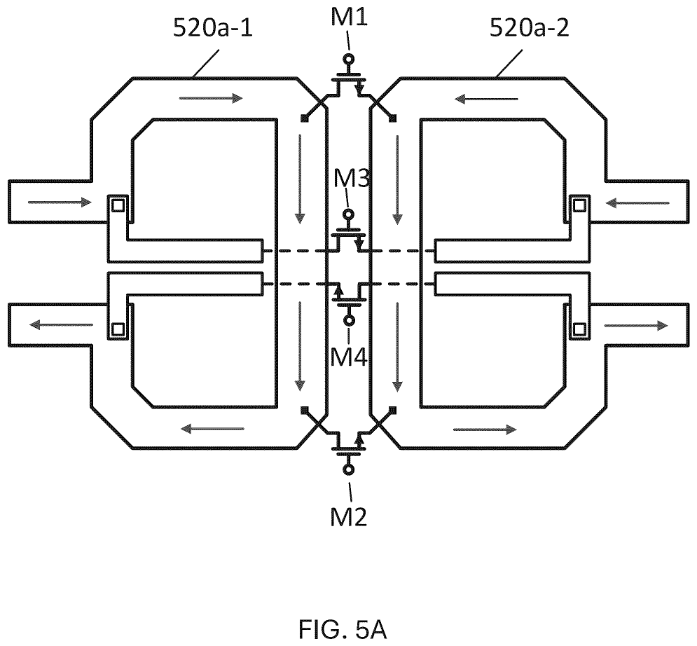

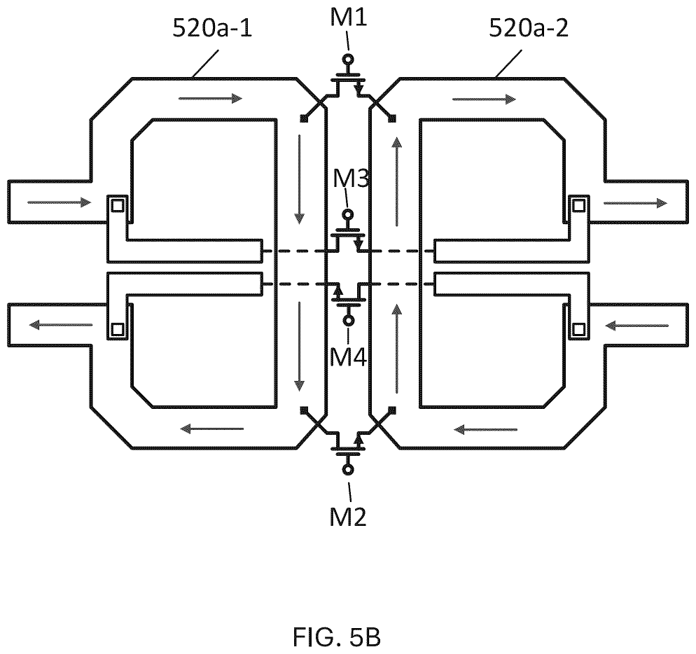

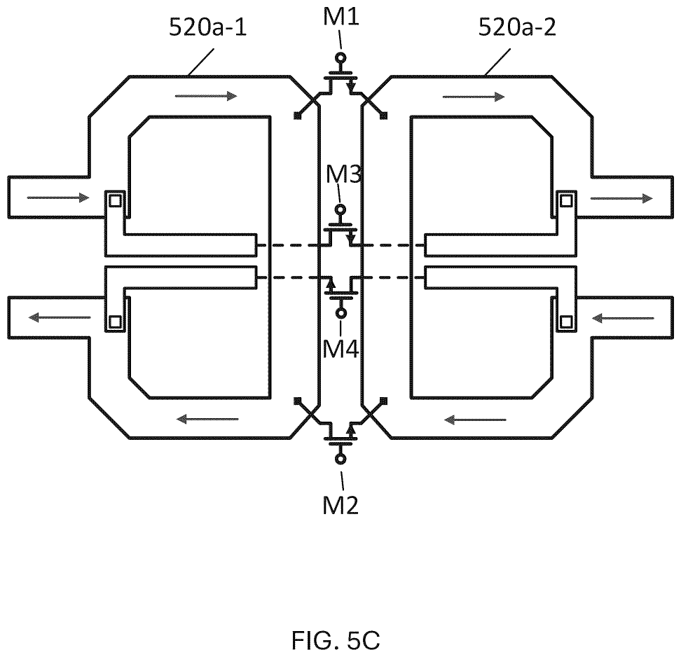

FIG. 5A is a diagram of a dual-core VCO operating in a first mode in which no current flows through the switching transistors, according to an embodiment. This figure corresponds to the reconfigurable VCO circuit of FIG. 1, with reference numerals updated in the 500-series. The dual-core VCO includes oscillator cores, each comprising inductors 520a-1 and 520a-2. The inductors 520a-1 and 520a-2 may be arranged in a parallel-coupled figure-8 layout, with arrows indicating the current flow directions through the inductors 520a-1 and 520a-2 during oscillation. In the first mode, current flow directions may be clockwise in inductor 520a-1 and counterclockwise in inductor 520a-2, forming axial symmetry which is the desired operation mode.

The inductors 520a-1 and 520a-2 may be coupled through transistors M1 and M2, which function as second switches. In dual-core operation, M1 and M2 are turned on, providing resistive and magnetic coupling between the oscillator cores. Transistors M3 and M4, may also function as second switches, are turned on such that a low-loss path may be created. This additional path may ensure the current flow directions in inductors 520a-1 and 520b-1 of first mode and enhance the phase alignment of the two cores so that a second and third mode are suppressed. Because M3 and M4 are sized to minimize parasitic capacitance while maintaining sufficient current drive, they may enable efficient operation with low phase noise. In this desired mode, inactive bottom cores (not shown in FIG. 5A) may remain off, and no current may flow through their associated transistors, ensuring that only the upper dual-core (the illustrated configuration FIG. 5A) participates in oscillation.

FIGS. 5B and 5C are diagrams illustrating second and third mode operation of the VCO circuit which are undesired, according to an embodiment. These figures contrast with FIG. 5A, which illustrated the desired dual-core operation, by showing current flow paths that give rise to unwanted oscillation modes. In these views, the directional arrows indicate the current flow paths within the inductors 520a-1 and 520a-2 during the undesired oscillation modes. In second mode, the current flow directions may be both clockwise in inductors 520a-1 and 520a-2. In third mode, the current flow direction may be horizontally left to right through M1 and right to left through M2. The VCO may oscillate between these modes arbitrarily with wrong frequency if they are not properly suppressed, which can cause system failure.

As illustrated in FIGS. 5B and 5C, the second switches (M1, M2) provided within each dual-core VCO must be properly sized. If the on-resistance of M1 or M2 is either too large or too small, undesired oscillation modes may occur, leading to degraded phase noise and instability. Another set of second switches (M3, M4), which couple the inductors 520a-1 and 520a-2 of the first and second dual-core VCOs, can also function to suppress unwanted-mode oscillations. By combining the operation of M1 and M2 with M3 and M4, unwanted modes can be effectively suppressed across process, voltage, and temperature (PVT) variations, while still allowing the switches to be kept small enough to reduce parasitic capacitance and minimize impact on overall VCO performance.

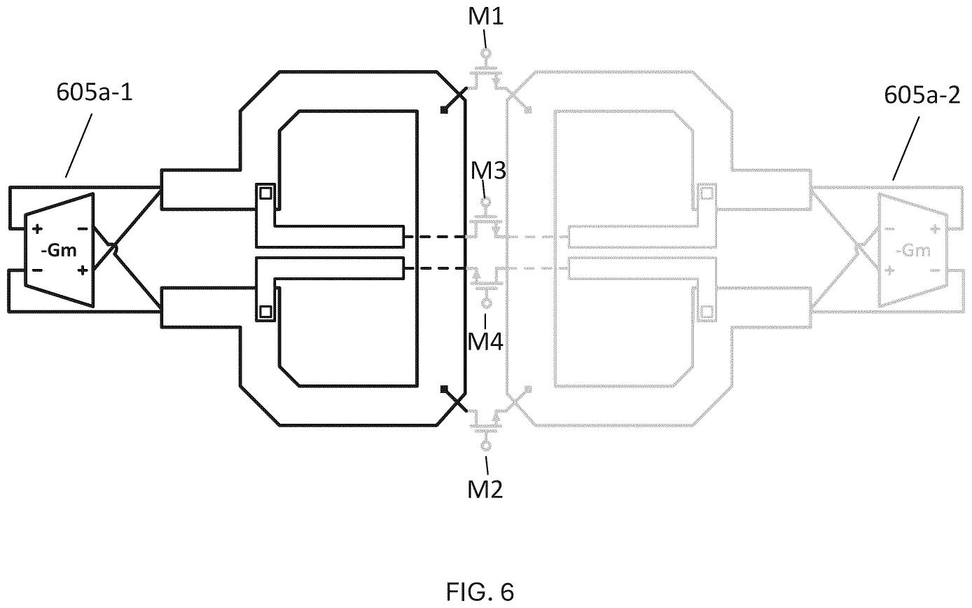

FIG. 6 is a diagram illustrating single-core mode operation of the VCO, according to an embodiment. Elements 605a-1 and 605a-2 shown in FIG. 6 may correspond to elements 305a-1 and 305a-2 shown in FIG. 3.

In this mode, only oscillator core 1 (605a-1) is active, while oscillator core 2 (605a-2) is turned off. The transistors M1-M4 are also turned off in this configuration. By disabling both the inactive oscillator core and the suppression transistors, the effect of the inductor associated with core 2 (605a-2) can be minimized, thereby reducing parasitic loading and improving single-core efficiency. This selective operation may allow the VCO to maintain oscillation using a single active core while achieving reduced power consumption and stable frequency characteristics.

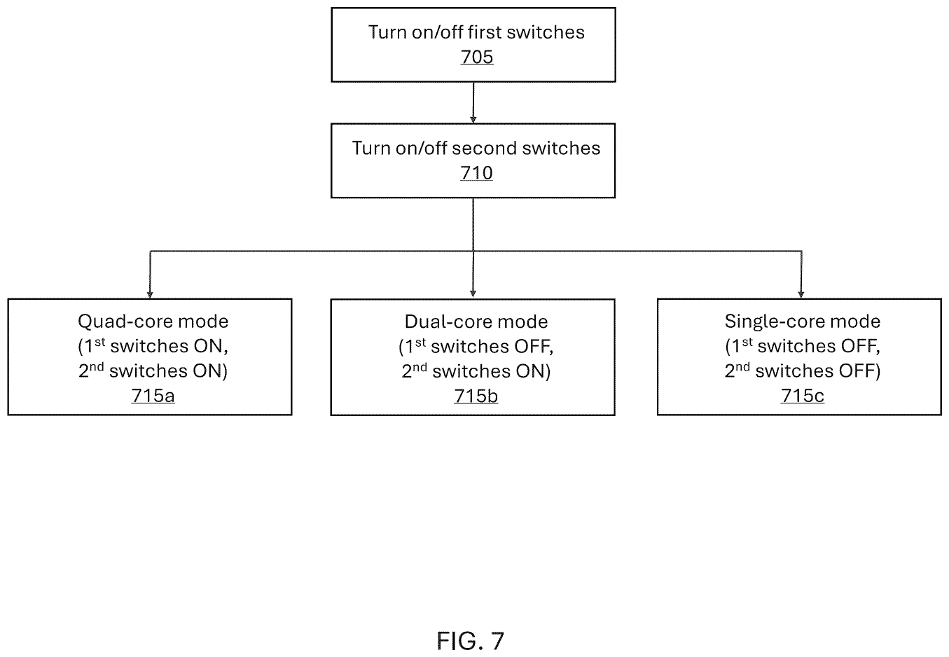

FIG. 7 is a flowchart illustrating a method of operating a VCO circuit, according to an embodiment. At step 705, first switches may be selectively turned on or off to connect or disconnect first and second dual-core VCOs disposed side-by-side. At step 710, second switches may be selectively turned on or off to connect or disconnect first and second oscillator cores of the first dual-core VCO, and to connect or disconnect third and fourth oscillator cores of the second dual-core VCO. Depending on the switching configuration, the VCO circuit may operate in one of multiple modes. In a quad-core mode (step 715a), both the first switches and the second switches are turned on, such that all oscillator cores are coupled. In a dual-core mode (step 715b), the first switches are turned off and at least some of the second switches are turned on, such that oscillator cores are coupled in pairs. In a single-core mode (step 715c), the first switches are turned off and at least some of the second switches are turned off, such that only one oscillator core operates while the other cores remain decoupled.

In one embodiment, the first and second switches may be implemented as transistors whose gate terminals receive control signals from a mode control logic circuit. The mode control logic may generate the control signals based on configuration commands from a frequency synthesizer or higher-level system controller, thereby determining whether the VCO circuit operates in quad-core, dual-core, or single-core mode.

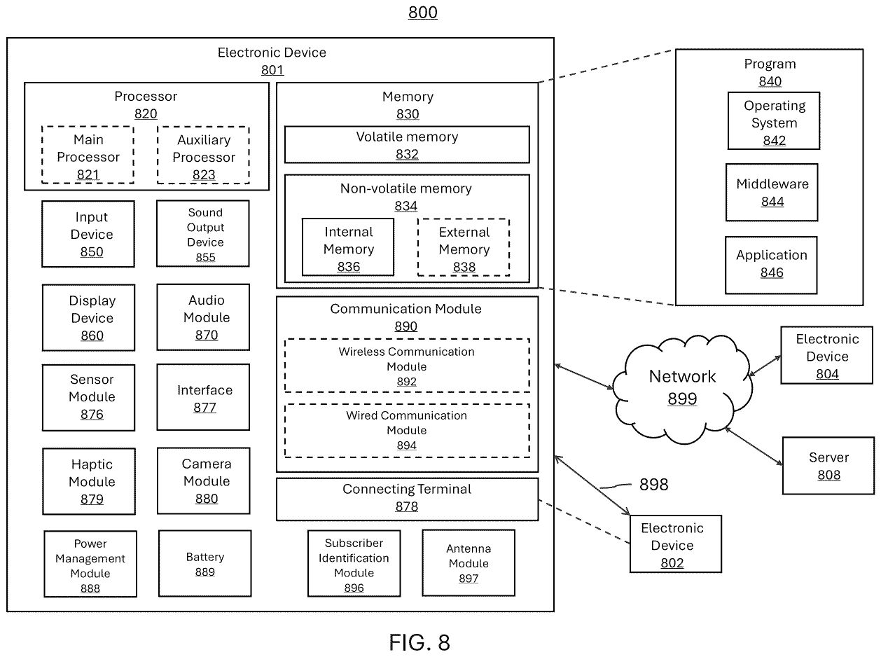

FIG. 8 is a block diagram of an electronic device in a network environment 800, according to an embodiment.

Referring to FIG. 8, an electronic device 801 in a network environment 800 may communicate with an electronic device 802 via a first network 898 (e.g., a short-range wireless communication network), or an electronic device 804 or a server 808 via a second network 899 (e.g., a long-range wireless communication network). The electronic device 801 may communicate with the electronic device 804 via the server 808. The electronic device 801 may include a processor 820, a memory 830, an input device 850, a sound output device 855, a display device 860, an audio module 870, a sensor module 876, an interface 877, a haptic module 879, a camera module 880, a power management module 888, a battery 889, a communication module 890, a subscriber identification module (SIM) card 896, or an antenna module 897. In one embodiment, at least one (e.g., the display device 860 or the camera module 880) of the components may be omitted from the electronic device 801, or one or more other components may be added to the electronic device 801. Some of the components may be implemented as a single integrated circuit (IC). For example, the sensor module 876 (e.g., a fingerprint sensor, an iris sensor, or an illuminance sensor) may be embedded in the display device 860 (e.g., a display).

The processor 820 may execute software (e.g., a program 840) to control at least one other component (e.g., a hardware or a software component) of the electronic device 801 coupled with the processor 820 and may perform various data processing or computations.

As at least part of the data processing or computations, the processor 820 may load a command or data received from another component (e.g., the sensor module 876 or the communication module 890) in volatile memory 832, process the command or the data stored in the volatile memory 832, and store resulting data in non-volatile memory 834. The processor 820 may include a main processor 821 (e.g., a central processing unit (CPU) or an application processor (AP)), and an auxiliary processor 823 (e.g., a graphics processing unit (GPU), an image signal processor (ISP), a sensor hub processor, or a communication processor (CP)) that is operable independently from, or in conjunction with, the main processor 821. Additionally or alternatively, the auxiliary processor 823 may be adapted to consume less power than the main processor 821, or execute a particular function. The auxiliary processor 823 may be implemented as being separate from, or a part of, the main processor 821.

The auxiliary processor 823 may control at least some of the functions or states related to at least one component (e.g., the display device 860, the sensor module 876, or the communication module 890) among the components of the electronic device 801, instead of the main processor 821 while the main processor 821 is in an inactive (e.g., sleep) state, or together with the main processor 821 while the main processor 821 is in an active state (e.g., executing an application). The auxiliary processor 823 (e.g., an image signal processor or a communication processor) may be implemented as part of another component (e.g., the camera module 880 or the communication module 890) functionally related to the auxiliary processor 823.

The memory 830 may store various data used by at least one component (e.g., the processor 820 or the sensor module 876) of the electronic device 801. The various data may include, for example, software (e.g., the program 840) and input data or output data for a command related thereto. The memory 830 may include the volatile memory 832 or the non-volatile memory 834. Non-volatile memory 834 may include internal memory 836 and/or external memory 838.

The program 840 may be stored in the memory 830 as software, and may include, for example, an operating system (OS) 842, middleware 844, or an application 846.

The input device 850 may receive a command or data to be used by another component (e.g., the processor 820) of the electronic device 801, from the outside (e.g., a user) of the electronic device 801. The input device 850 may include, for example, a microphone, a mouse, or a keyboard.

The sound output device 855 may output sound signals to the outside of the electronic device 801. The sound output device 855 may include, for example, a speaker or a receiver. The speaker may be used for general purposes, such as playing multimedia or recording, and the receiver may be used for receiving an incoming call. The receiver may be implemented as being separate from, or a part of, the speaker.

The display device 860 may visually provide information to the outside (e.g., a user) of the electronic device 801. The display device 860 may include, for example, a display, a hologram device, or a projector and control circuitry to control a corresponding one of the display, hologram device, and projector. The display device 860 may include touch circuitry adapted to detect a touch, or sensor circuitry (e.g., a pressure sensor) adapted to measure the intensity of force incurred by the touch.

The audio module 870 may convert a sound into an electrical signal and vice versa. The audio module 870 may obtain the sound via the input device 850 or output the sound via the sound output device 855 or a headphone of an external electronic device 802 directly (e.g., wired) or wirelessly coupled with the electronic device 801.

The sensor module 876 may detect an operational state (e.g., power or temperature) of the electronic device 801 or an environmental state (e.g., a state of a user) external to the electronic device 801, and then generate an electrical signal or data value corresponding to the detected state. The sensor module 876 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 877 may support one or more specified protocols to be used for the electronic device 801 to be coupled with the external electronic device 802 directly (e.g., wired) or wirelessly. The interface 877 may include, for example, a high-definition multimedia interface (HDMI), a universal serial bus (USB) interface, a secure digital (SD) card interface, or an audio interface.

A connecting terminal 878 may include a connector via which the electronic device 801 may be physically connected with the external electronic device 802. The connecting terminal 878 may include, for example, an HDMI connector, a USB connector, an SD card connector, or an audio connector (e.g., a headphone connector).

The haptic module 879 may convert an electrical signal into a mechanical stimulus (e.g., a vibration or a movement) or an electrical stimulus which may be recognized by a user via tactile sensation or kinesthetic sensation. The haptic module 879 may include, for example, a motor, a piezoelectric element, or an electrical stimulator.

The camera module 880 may capture a still image or moving images. The camera module 880 may include one or more lenses, image sensors, image signal processors, or flashes. The power management module 888 may manage power supplied to the electronic device 801. The power management module 888 may be implemented as at least part of, for example, a power management integrated circuit (PMIC).

The battery 889 may supply power to at least one component of the electronic device 801. The battery 889 may include, for example, a primary cell which is not rechargeable, a secondary cell which is rechargeable, or a fuel cell.

The communication module 890 may support establishing a direct (e.g., wired) communication channel or a wireless communication channel between the electronic device 801 and the external electronic device (e.g., the electronic device 802, the electronic device 804, or the server 808) and performing communication via the established communication channel. The communication module 890 may include one or more communication processors that are operable independently from the processor 820 (e.g., the AP) and supports a direct (e.g., wired) communication or a wireless communication. The communication module 890 may include a wireless communication module 892 (e.g., a cellular communication module, a short-range wireless communication module, or a global navigation satellite system (GNSS) communication module) or a wired communication module 894 (e.g., a local area network (LAN) communication module or a power line communication (PLC) module). A corresponding one of these communication modules may communicate with the external electronic device via the first network 898 (e.g., a short-range communication network, such as BLUETOOTH™, wireless-fidelity (Wi-Fi) direct, or a standard of the Infrared Data Association (IrDA)) or the second network 899 (e.g., a long-range communication network, such as a cellular network, the Internet, or a computer network (e.g., LAN or wide area network (WAN)). These various types of communication modules may be implemented as a single component (e.g., a single IC), or may be implemented as multiple components (e.g., multiple ICs) that are separate from each other. The wireless communication module 892 may identify and authenticate the electronic device 801 in a communication network, such as the first network 898 or the second network 899, using subscriber information (e.g., international mobile subscriber identity (IMSI)) stored in the subscriber identification module 896.

The antenna module 897 may transmit or receive a signal or power to or from the outside (e.g., the external electronic device) of the electronic device 801. The antenna module 897 may include one or more antennas, and, therefrom, at least one antenna appropriate for a communication scheme used in the communication network, such as the first network 898 or the second network 899, may be selected, for example, by the communication module 890 (e.g., the wireless communication module 892). The signal or the power may then be transmitted or received between the communication module 890 and the external electronic device via the selected at least one antenna.

Commands or data may be transmitted or received between the electronic device 801 and the external electronic device 804 via the server 808 coupled with the second network 899. Each of the electronic devices 802 and 804 may be a device of a same type as, or a different type, from the electronic device 801. All or some of operations to be executed at the electronic device 801 may be executed at one or more of the external electronic devices 802, 804, or 808. For example, if the electronic device 801 should perform a function or a service automatically, or in response to a request from a user or another device, the electronic device 801, instead of, or in addition to, executing the function or the service, may request the one or more external electronic devices to perform at least part of the function or the service. The one or more external electronic devices receiving the request may perform the at least part of the function or the service requested, or an additional function or an additional service related to the request and transfer an outcome of the performing to the electronic device 801. The electronic device 801 may provide the outcome, with or without further processing of the outcome, as at least part of a reply to the request. To that end, a cloud computing, distributed computing, or client-server computing technology may be used, for example.

In some embodiments, the method of operating the VCO circuit described herein may be performed within a transceiver of the electronic device 801. For example, the communication module 890, and in particular its wireless communication module 892, may include a frequency synthesizer circuit having the VCO and associated switching elements. In such embodiments, the processor 820 (e.g., the main processor 821 or the auxiliary processor 823) may provide control signals to the transceiver to selectively turn on or off the first and second switches, thereby configuring the VCO for quad-core, dual-core, or single-core operation. The power management module 888 may further support these operations by regulating bias currents and supply voltages applied to the oscillator cores. Thus, the method may be implemented in the transceiver circuitry of the communication module 890 under the control of the processor 820, enabling mode selection of the VCO for improved phase noise performance and power efficiency during wireless communication.

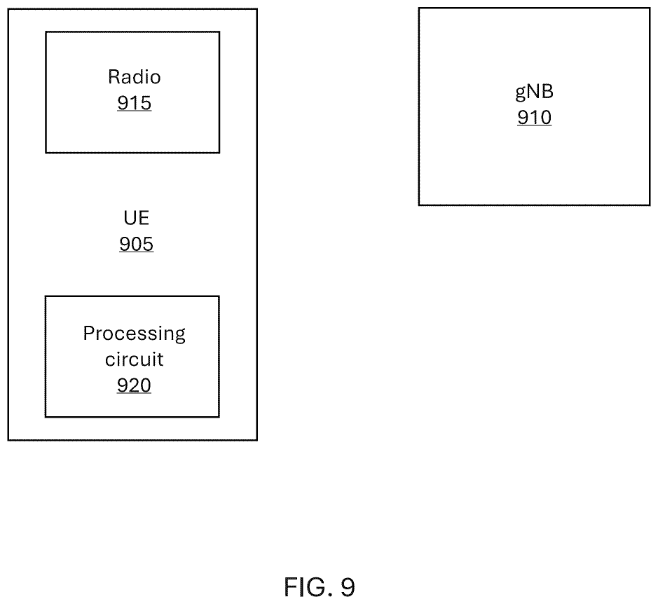

FIG. 9 shows a system including a UE 905 and a gNB 910, in communication with each other. The UE may include a radio 915 and a processing circuit (or a means for processing) 920, which may perform various methods disclosed herein, e.g., the method illustrated in FIG. 1. For example, the processing circuit 920 may receive, via the radio 915, transmissions from the network node (gNB) 910, and the processing circuit 920 may transmit, via the radio 915, signals to the gNB 910.

Some embodiments may be implemented in the transceiver circuitry of the radio 915 of the UE 905 and/or the gNB 910, where the VCO forms part of a frequency synthesizer for the transceiver. The processing circuit 920 may provide control signals to the transceiver to configure the VCO mode, thereby enabling quad-core, dual-core, or single-core operation during wireless communication.

Embodiments of the subject matter and the operations described in this specification may be implemented in digital electronic circuitry, or in computer software, firmware, or hardware, including the structures disclosed in this specification and their structural equivalents, or in combinations of one or more of them. Embodiments of the subject matter described in this specification may be implemented as one or more computer programs, i.e., one or more modules of computer-program instructions, encoded on computer-storage medium for execution by, or to control the operation of data-processing apparatus. Alternatively or additionally, the program instructions can be encoded on an artificially-generated propagated signal, e.g., a machine-generated electrical, optical, or electromagnetic signal, which is generated to encode information for transmission to suitable receiver apparatus for execution by a data processing apparatus. A computer-storage medium can be, or be included in, a computer-readable storage device, a computer-readable storage substrate, a random or serial-access memory array or device, or a combination thereof. Moreover, while a computer-storage medium is not a propagated signal, a computer-storage medium may be a source or destination of computer-program instructions encoded in an artificially-generated propagated signal. The computer-storage medium can also be, or be included in, one or more separate physical components or media (e.g., multiple CDs, disks, or other storage devices). Additionally, the operations described in this specification may be implemented as operations performed by a data-processing apparatus on data stored on one or more computer-readable storage devices or received from other sources.

While this specification may contain many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

As will be recognized by those skilled in the art, the innovative concepts described herein may be modified and varied over a wide range of applications. Accordingly, the scope of claimed subject matter should not be limited to any of the specific exemplary teachings discussed above, but is instead defined by the following claims.

What is claimed is:

1. A voltage-controlled oscillator (VCO) circuit comprising:
a first dual-core VCO including a first oscillator core and a second oscillator core;
a second dual-core VCO including a third oscillator core and a fourth oscillator core, wherein the first and second dual-core VCOs are disposed side-by-side;
first switches configured to connect or disconnect the first and second dual-core VCOs from each other; and
second switches configured to connect or disconnect the first and second oscillator from each other, and to connect or disconnect the third and fourth oscillator cores from each other.

2. The VCO of claim 1, wherein the first switches comprise transistors configured to couple inductors of the first and second dual-core VCOs.

3. The VCO of claim 1, wherein the second switches comprise transistors configured to couple inductors of the first and second oscillator cores.

4. The VCO of claim 1, wherein the second switches comprise transistors configured to couple inductors of the third and fourth oscillator cores.

5. The VCO of claim 1, wherein a horizontal distance between the first and second dual core VCOs is in a range of 10 micrometers to 50 micrometers.

6. The VCO of claim 1, wherein at least one of the first switches comprises a transistor having a size in a range of 10 micrometers to 50 micrometers.

7. The VCO of claim 1, wherein at least one of the second switches comprises a transistor having a size in a range of 50 micrometers to 200 micrometers.

8. The VCO of claim 1, wherein the VCO is configured to operate in a quad-core mode, a dual-core mode and a single-core mode.

9. The VCO of claim 1, wherein the second switches are configured to suppress unwanted oscillation modes in a dual-core mode and to decouple inactive oscillator cores in a single-core mode.

10. The VCO of claim 1, wherein each of the first and second dual-core VCOs comprises an inductor structure configured to magnetically couple its oscillator cores.

11. The VCO of claim 10, wherein the inductor structure comprises a figure-8 inductor layout.

12. A transceiver, comprising:
a voltage-controlled oscillator (VCO) including:
a first dual-core VCO including a first oscillator core and a second oscillator core;
a second dual-core VCO including a third oscillator core and a fourth oscillator core, wherein the first and second dual-core VCOs are disposed side-by-side;
first switches configured to connect or disconnect the first and second dual-core VCOs from each other; and
second switches configured to connect or disconnect the first and second oscillator from each other, and to connect or disconnect the third and fourth oscillator cores from each other.

13. The transceiver of claim 12, wherein the transceiver is configured for millimeter-wave communication.

14. The transceiver of claim 12, wherein the first switches comprise transistors configured to couple inductors of the first and second dual-core VCOs.

15. The transceiver of claim 12, wherein the second switches comprise transistors configured to couple inductors of the first and second oscillator cores.

16. The transceiver of claim 12, wherein the second switches comprise transistors configured to couple inductors of the third and fourth oscillator cores.

17. The transceiver of claim 12, wherein a horizontal distance between the first and second dual core VCOs is in a range of 10 micrometers to 50 micrometers.

18. The transceiver of claim 12, wherein the second switches are configured to suppress unwanted oscillation modes in a dual-core mode and to decouple inactive oscillator cores in a single-core mode.

19. A method of operating a voltage-controlled oscillator (VCO) circuit, comprising:
selectively turning on or off first switches to connect or disconnect a first dual-core VCO and a second dual-core VCO from each other, wherein the first and second dual-core VCOs are disposed side-by-side; and
selectively turning on or off second switches to connect or disconnect first and second oscillator cores of the first dual-core VCO from each other, and to connect or disconnect the third and fourth oscillator cores of the second dual-core VCO from each other.

20. The method of claim 19, further comprising operating the VCO circuit in a quad-core mode by turning on both the first switches and the second switches.

21. The method of claim 19, further comprising operating the VCO circuit in a dual-core mode by turning off the first switches and turning on at least some of the second switches.

22. The method of claim 19, further comprising operating the VCO circuit in a single-core mode by turning off the first switches and turning off at least some of the second switches.

23. The method of claim 19, wherein the second switches suppress unwanted oscillation modes in the dual-core mode and decouple inactive oscillator cores in the single-core mode.
